(19) United States
(12) Patent Application Publication
(10) Pub. No.: US 2012/0119185 A1
(43) Pub. Date: May 17, 2012

(54) ACTIVE LAYER FOR SILICON LIGHT-EMITTING DEVICES AND METHOD FOR MANUFACTURING THE SAME

(75) Inventor: Hideo Iwase, Kawasaki-shi (JP)

(73) Assignee: CANON KABUSHIKI KAISHA, Tokyo (JP)

(21) Appl. No.: 13/291,954

(22) Filed: Nov. 8, 2011

(30) Foreign Application Priority Data
Nov. 16, 2010 (JP) 2010-256310

(51) Int. Cl. H01L 33/04; B82Y 40/00; B82Y 99/00

(52) U.S. Cl. 257/13; 438/37; 977/773

(57) ABSTRACT

An active layer for silicon light-emitting devices has a layered film structure of first and second layers alternately stacked on a substrate. The first layer contains a silicon compound, and the second layer contains another silicon compound and has a larger band gap than the first layer. The layered film structure contains silicon nanoparticles. The first layer contains more silicon atoms than the second layer, and at least one of the silicon nanoparticles exists across at least one of the interfacial boundaries between the first layer and the second layer.

### BACKGROUND OF THE INVENTION

1. Field of the Invention

The present invention relates to an active layer for silicon light-emitting devices and a method for manufacturing the active layer.

2. Description of the Related Art

Silicon is a semiconductor having a band gap of approximately 1.2 eV between electrons and holes having different wave number vectors. This type of semiconductor is referred to as indirect transition semiconductors, in which carriers recombine and emit light with the help of phonon scattering. In general, this phonon-induced carrier recombination hardly occurs at room temperature, and it is difficult to use silicon as a material of the active layer of light-emitting devices.

However, recent research has revealed silicon nanoparticles having a diameter of 1 to 20 nm offer sufficient quantum efficiency for the element to work in the active layer of light-emitting devices, and light-emitting devices based on silicon nanoparticles are now under active development.

FIG. 7 illustrates the structure of a silicon-nanoparticle light-emitting device. In FIG. 7, the active layer 800 is composed of silicon nanoparticles 802 and a barrier region 804 surrounding the silicon nanoparticles 802. The material of the barrier region 804 has a larger band gap than the silicon nanoparticles 802. Examples of the material of the barrier region 804 include silicon oxides and silicon nitrides. The active layer 800 is sandwiched between a hole diffusion layer 810 and an electron diffusion layer 820 so that carriers can be uniformly injected thereinto.

Usually, the hole diffusion layer 810 is made of p-doped silicon, and the electron diffusion layer 820 is an electrode made of indium tin oxide (ITO) or any other transparent material. Other semiconductors, such as doped forms of SiC, GaAs, and GaN, may also be used as the material of the hole diffusion layer 810 and that of the electron diffusion layer 820 instead.

The hole diffusion layer 810 and the electron diffusion layer 820 are connected to a power supply 850 via an anode 830 and a cathode 840. Carriers (electrons and holes), generated by the power supply 850 and passing through the hole diffusion layer 810 and the electron diffusion layer 820, are injected by tunneling into the silicon nanoparticles 802, and there recombine and emit light. The wavelength of the emitted light depends on the diameter of the silicon nanoparticles 802: nanoparticles having a diameter of approximately 1 to 3 nm emit visible light, and those having a diameter greater than approximately 1 to 3 nm emit near-infrared light.

Unfortunately, light-emitting devices containing this type of nanoparticles in their active layer have the problem of low brightness because some of the carriers miss the nanoparticles and undergo non-radiative recombination. FIG. 8 explains this phenomenon.

FIG. 8 is a schematic diagram illustrating pathways of carriers moving in an active layer. To simplify the explanation, this drawing only gives pathways of electrons; those of holes are omitted. As indicated by the pathways 910, electrons 920 migrate in a barrier region 804 and enter nanoparticles 802. However, some electrons miss the nanoparticles 802 and reach a hole diffusion layer 810, like the electrons 930 in the dashed ellipse in FIG. 8. After the failure to enter the nanoparticles 802 and the arrival at the hole diffusion layer 810, the electrons undergo non-radiative recombination with holes. Thus, carriers should be guided into nanoparticles by some means.

Japanese Patent Laid-Open No. 2006-229010 discloses a method for guiding carriers into nanoparticles in a GaAs system. In this method, two kinds of semiconductor layers having different band gaps are alternately stacked, and nanoparticles are embedded in one of the pair of semiconductor layers having a lower band gap (the low-band-gap layer). The other of the pair of semiconductor layers, which has a higher band gap (the high-band-gap layer), blocks carriers.

FIG. 9 illustrates a cross-section of the active layer described in that patent publication, Japanese Patent Laid-Open No. 2006-229010. In FIG. 9, the active layer 1000 is composed of nanoparticles in the form of mixed crystals of arsenic (As) and a group-III element (quantum dots 1030), an InGaAsP barrier layer 1020 formed on them, and an InAlGaAs barrier layer 1010 formed on it.

In this structure, the InAlGaAs barrier layer 1010 has a larger band gap than the InGaAsP barrier layer 1020. Therefore, the InAlGaAs barrier layer 1010 is the high-band-gap layer, and the InGaAsP barrier layer 1020 is the low-band-gap layer.

When carriers flow from the top and the bottom of FIG. 9, the InAlGaAs barrier layer 1010 blocks the carriers moving in the directions perpendicular to the substrate, serving as a carrier-blocking layer. The carrier-blocking layer restricts the nearby electrons from moving in the directions perpendicular to the substrate, and the restricted carriers are more likely to diffuse in the directions parallel to the substrate.

Once the carriers diffusing in the directions parallel to the substrate reach the quantum dots 1030, the difference in potential between the quantum dots 1030 and the InGaAsP barrier layer 1020 acts to attract and take them into the quantum dots 1030. In summary, the structure in which two kinds of semiconductors having different band gaps are alternately stacked and nanoparticles are embedded in the low-band-gap layer restricts carriers from moving in the directions perpendicular to the substrate and reduces the number of carriers missing the nanoparticles and passing through the active layer. In such a structure, furthermore, the carriers are more likely to diffuse in the directions parallel to the substrate and to enter the nanoparticles, and this results in an improved luminous efficiency.

However, this method, disclosed in Japanese Patent Laid-Open No. 2006-229010, cannot be directly applied to silicon nanoparticles because the light-emitting devices manufactured by that method will require a high voltage to drive. The following explains this problem in detail with reference to FIG. 10.

In FIG. 10, the active layer 1100 is a layered film composed of a SiO₂ layer 1110 and a Si₃N₄ layer 1120 alternately stacked. Si₃N₄ has a smaller band gap than SiO₂: approximately 5 eV compared with approximately 8 eV. Silicon nanoparticles 1130 are embedded in the Si₃N₄ layer 1120, the low-band-gap layer. The band gap of the Si₃N₄ layer 1120 is larger than that of the silicon nanoparticles 1130 (1.1 eV); therefore, the Si₃N₄ layer 1120 serves as a barrier region for the silicon nanoparticles 1130.

Furthermore, the band gap of the SiO₂ layer 1110 is larger than that of the Si₃N₄ layer 1120; therefore, the SiO₂ layer 1110 serves as a carrier-blocking layer.

An electron 1160, blocked by the SiO₂ layer 1110, can take two pathways to reach a silicon nanoparticle 1130. One is the pathway 1150, diffusion in a direction parallel to the substrate to reach a silicon nanoparticle, and the other is the pathway 1140, penetration through the SiO₂ layer 1110 to reach a silicon nanoparticle 1130 in the next layer.

When electrons penetrate the SiO₂ layer 1110, the working mechanism is tunneling because of the large difference in band gap between the Si₃N₄ layer 1120 and the SiO₂ layer 1110. In other words, the number of penetrating electrons per unit time depends on the thickness of the SiO₂ layer 1110.

If the thickness of the SiO₂ layer 1110 is increased to reduce the probability that electrons can penetrate the SiO₂ layer 1110, the diffusion in horizontal directions (white arrow) speeds up, while the number of electrons reaching silicon nanoparticles 1130 by tunneling (black arrow) declines.

If the thickness of the SiO₂ layer 1110 is reduced to increase the probability that electrons can penetrate the SiO₂ layer 1110, however, the number of electrons reaching silicon nanoparticles 1130 by tunneling (black arrow) rises, while the diffusion in horizontal directions (white arrow) slows down.

In this way, it is difficult to achieve high efficiency both in carrier diffusion in the directions parallel to the substrate and in carrier injection by tunneling simply by changing the thickness of the SiO₂ layer 1110.

### SUMMARY OF THE INVENTION

The present invention provides an active layer for silicon light-emitting devices that allows for carrier diffusion in the directions parallel to the substrate and carrier injection in the directions perpendicular to the substrate both at high efficiency, and it also provides a method for manufacturing this active layer.

The active layer for silicon light-emitting devices according to the present invention has: a layered film structure of first and second layers alternately stacked on a substrate, the first layer containing a silicon compound whereas the second layer containing another silicon compound and having a larger band gap than the first layer; and silicon nanoparticles contained in the layered film structure and emitting light on carrier injection, wherein: the first layer contains more silicon atoms than the second layer; and the silicon nanoparticles are formed to exist across at least one of the interfacial boundaries between the first layer and the second layer.

### Advantages

The active layer for silicon light-emitting devices according to the present invention is advantageous in that it allows for carrier diffusion in the directions parallel to the substrate and carrier injection in the direction perpendicular to the substrate both at high efficiency. Furthermore, a method for manufacturing this active layer is also provided.

Further features of the present invention will become apparent from the following description of exemplary embodiments with reference to the attached drawings.

### BRIEF DESCRIPTION OF THE DRAWINGS

FIG. 1 illustrates an active layer according to an embodiment of the present invention.

FIG. 2 is a diagram for explaining an advantage of an embodiment of the present invention.

FIG. 3 illustrates the probability that carriers can penetrate a silicon oxide film by tunneling.

FIG. 4 is a diagram for explaining a method for manufacturing an active layer according to an embodiment of the present invention.

FIG. 5A illustrates the constitution of an active layer according to another embodiment, and FIG. 5B is a diagram for explaining a method for manufacturing this active layer.

FIG. 6 is a diagram for explaining a method for manufacturing an active layer according to yet another embodiment.

FIG. 7 illustrates a known type of silicon light-emitting device.

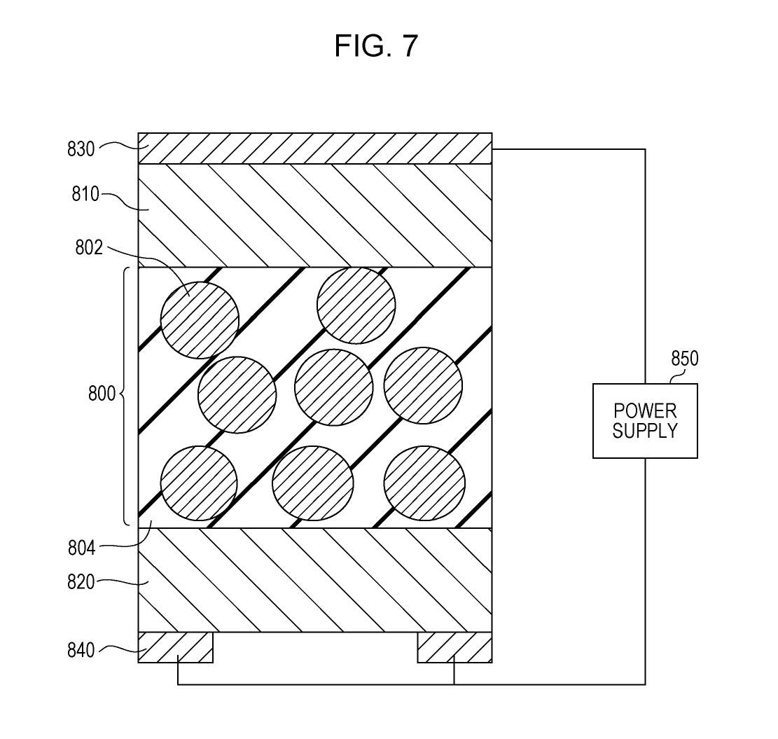

FIG. 8 illustrates another known type of silicon light-emitting device.

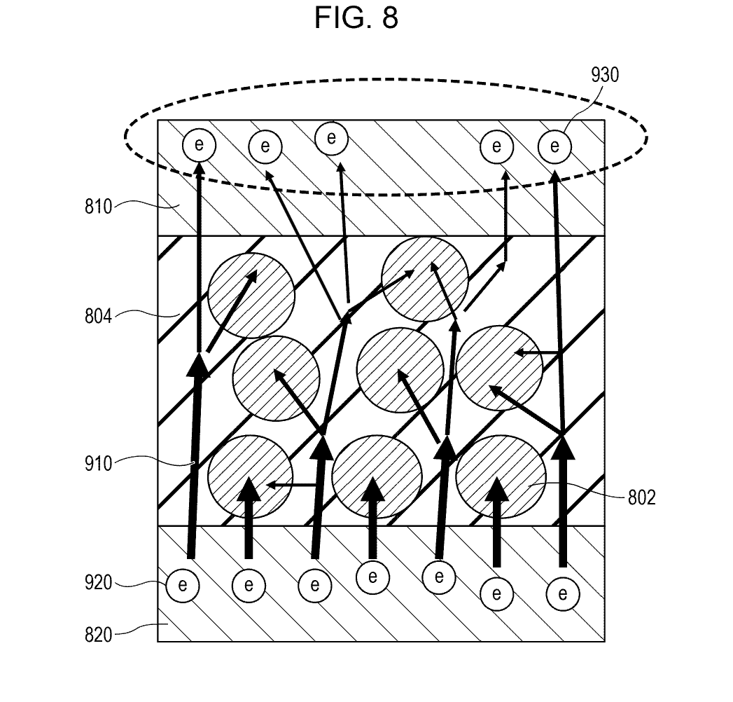

FIG. 9 illustrates yet another known type of silicon light-emitting device.

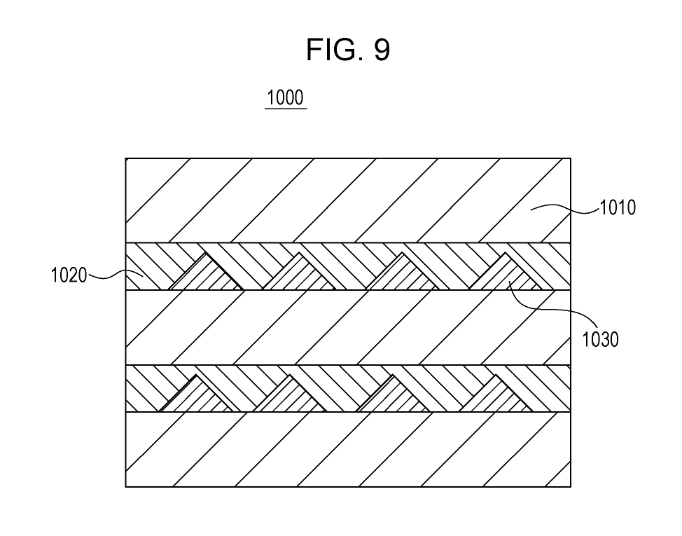

FIG. 10 is a diagram for explaining a problem the present invention solves.

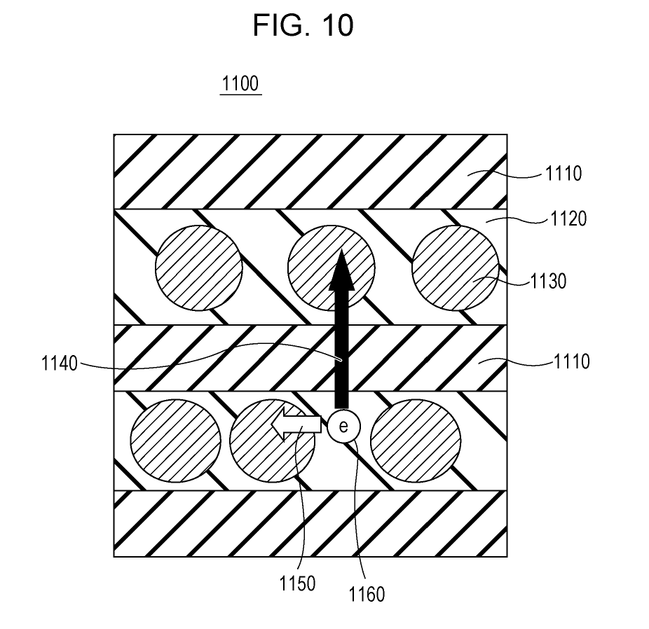

### DESCRIPTION OF THE EMBODIMENTS

The following describes some embodiments of the present invention with reference to the attached drawings.

### First Embodiment

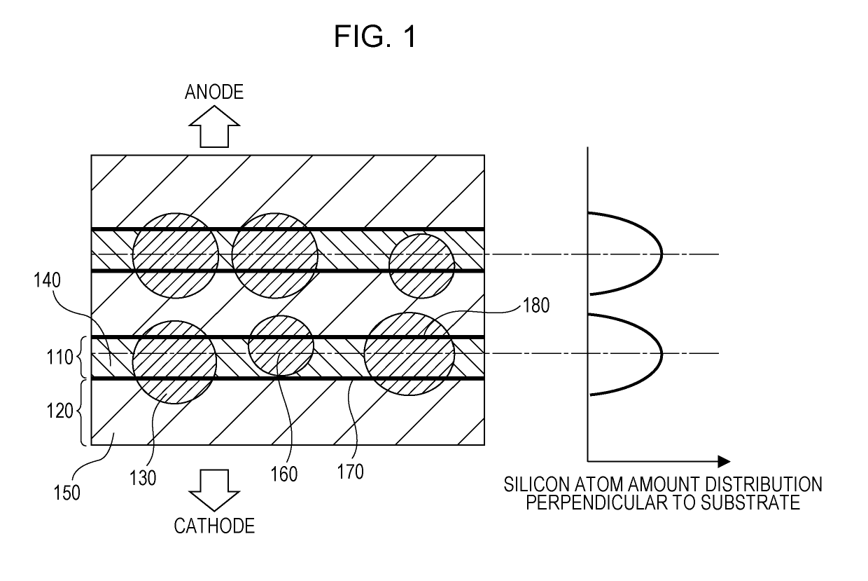

FIG. 1 is a cross-sectional diagram illustrating an embodiment of the present invention, an active layer for silicon light-emitting devices.

In this embodiment, the active layer has a layered film structure of a first layer 110 and a second layer 120 alternately stacked on a substrate.

The first layer 110 contains a silicon compound 140 and silicon nanoparticles 130, whereas the second layer 120 contains another silicon compound 150, which has a different composition from that in the first layer 110, and shares the silicon nanoparticles 130. The silicon nanoparticles 130 are formed to exist across at least one of the interfacial boundaries 170 and 180 between the first layer 110 and the second layer 120. And, the second layer 120 has a larger band gap than the first layer 110.

FIG. 1 also presents the distribution of the amount of silicon atoms in a direction perpendicular to the substrate. As can be seen from the chart, the first layer 110 contains more silicon atoms than the second layer 120. The distribution of the amount of silicon atoms in a direction perpendicular to a substrate can be determined by analytical methods such as secondary ion mass spectrometry (SIMS).

The composition mentioned here represents the combination of all constituent elements of the compound except impurities.

Thus, one compound shares the same composition with another when the two compounds have the same combination of elements, regardless of the relative amounts of the individual elements. For example, the stoichiometric silicon nitride shares the same composition with nonstoichiometric silicon nitrides.

And, one compound has a different composition from another when the two compounds have different combinations of elements. For example, silicon nitrides have a different composition from silicon oxides.

As described above, the band gap should be lower in the first layer 110 than in the second layer 120. This requirement can be satisfied by appropriately choosing the material of the first layer 110 and that of the second layer 120 from the compositions listed in Table below.

For example, when the composition of the silicon compound for the first layer 110 consists of silicon (Si) and carbon (C), that of the silicon compound for the second layer 120 can consist of either Si and oxygen (O) or Si and nitrogen (N). When the composition of the silicon compound for the first layer 110 consists of Si and N, that of the silicon compound for the second layer 120 can consist of either Si and O or Si, O, and N.

TABLE

| Composition | Stoichiometric formula | Band gap | |
|---|---|---|---|
| Si, N | Si₃N₄ | Approx. 5 | eV |
| Si, O | SiO₂ | Approx. 8 | eV |
| Si, C | SiC | Approx. 3 | eV |
| Si, N, O | (SiO₂)ₓ(Si₃N₄)₁₋ₓ | Approx. 5 to 8 | eV |

In a silicon compound, holes have a greater effective mass than electrons and are accordingly less mobile in migration by diffusion or tunneling. Thus, the silicon compounds listed in Table may be doped with Al, B, and Ga as p-type dopants that help holes diffuse.

The following describes operations and advantages of this embodiment with reference to examples, in which the composition of the silicon compound for the first layer 110 consists of Si and N, and that of the silicon compound for the second layer 120 either Si and O or Si, O, and N.

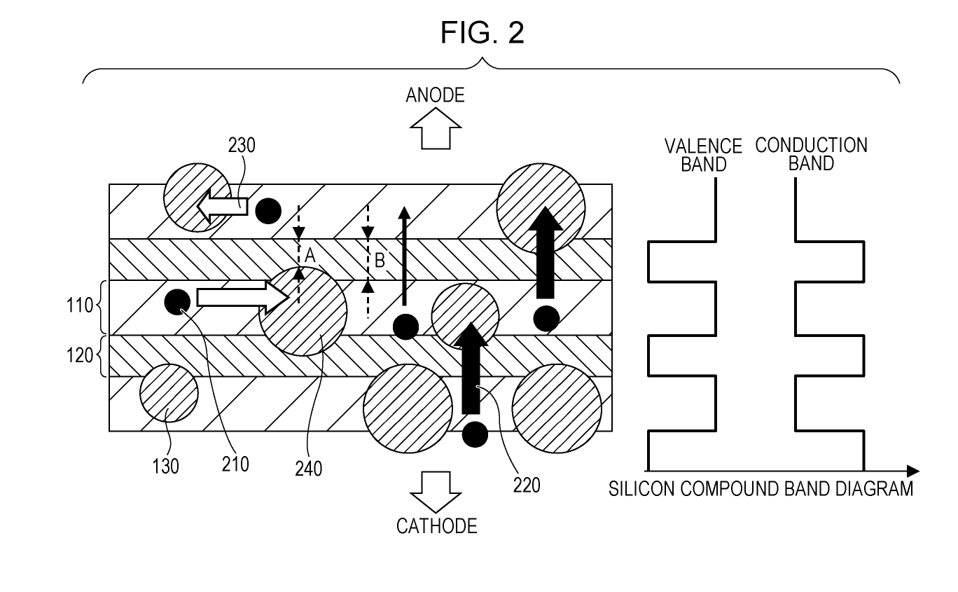

FIG. 2 is used here to explain operations and advantages of this embodiment. FIG. 2 includes a cross-sectional diagram of the active layer and a band diagram of the silicon compounds constituting the active layer.

The silicon compound contained in the first layer 110 is a silicon nitride consisting of silicon and nitrogen, whereas that in the second layer 120 is a silicon oxide consisting of silicon and oxygen.

The silicon oxide contained in the second layer 120 has a larger band gap than the silicon nitride contained in the first layer 110: approximately 8 eV compared with approximately 5 eV. Thus, the second layer 120 serves in the active layer as a carrier-blocking layer and restricts carriers from moving in any directions other than the horizontal. In other words, carriers become more likely to migrate in the directions parallel to the substrate (white arrows 230). The carriers diffusing to move in horizontal directions reach and enter silicon nanoparticles 130 and emit light.

However, some carriers penetrate the potential barrier of the second layer 120 (silicon oxide) by tunneling (solid black arrows 220). In general, the probability that particles can penetrate a potential barrier by tunneling is proportional to |T|² given by the following equation:

|T|²=exp└−2d\sqrt{2m*(φ−E)/ [symbol] ²}┘ [Equation 1]

In this equation, d represents the thickness of the potential barrier, φ−E the magnitude of the potential barrier, and m* the effective mass of the particles.

And, [symbol] can be derived from Planck constant by the following equation:

h≡2π [symbol] [Equation 2]

The probability that particles can penetrate a potential barrier sharply drops as the thickness of the barrier d increases. In this embodiment of the present invention, the silicon nanoparticles 130 are formed to exist across the interfacial boundaries between the first layer 110 and the second layer 120; therefore, the portion of the second layer 120 in contact with a silicon nanoparticle 130 (thickness A indicated by dashed arrows) is thinner than the portion of the second layer 120 out of contact with a silicon nanoparticle 130 (thickness B indicated by dashed arrows).

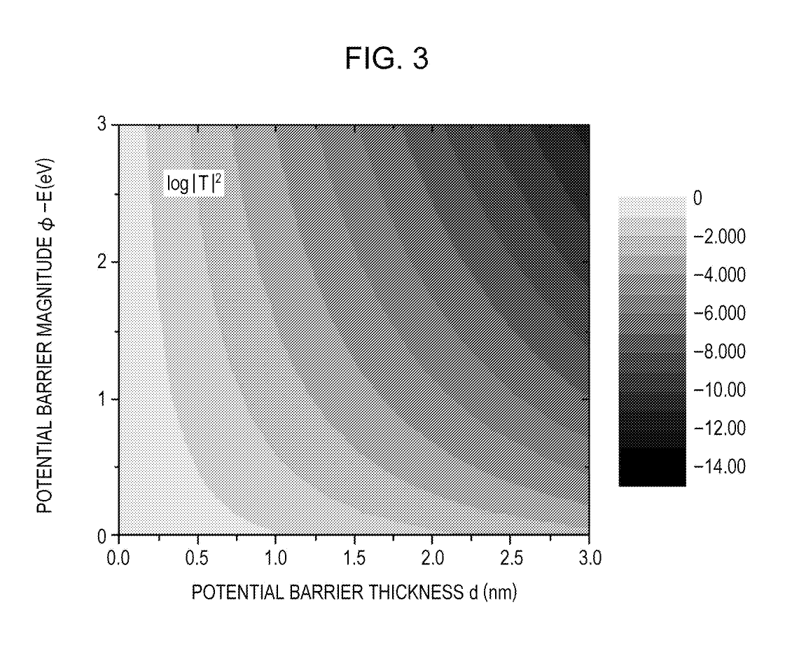

FIG. 3 illustrates the probability that electrons can penetrate a potential barrier by tunneling, mapped by the barrier's thickness d versus magnitude φ−E. As can be seen from FIG. 3, changes of 0.5 nm in thickness d lead to changes in penetration probability by at least one order of magnitude. For example, when thickness A of the silicon oxide layer is thinner than thickness B by 0.5 nm or more, the penetration probability of carriers moving toward silicon nanoparticles increases by a factor of at least ten, according to FIG. 3.

This type of carrier tunneling can occur when silicon nanoparticles are formed to exist across at least one of the interfacial boundaries between the first layer and the second layer.

However, there can be silicon particles existing across both the interfacial boundaries between the first layer 110 and the second layer 120 like that indicated by the reference numeral 240. In this constitution, both electrons and holes are injected selectively into a single silicon nanoparticle.

Also, the second layer still has a larger band gap than the first layer even when the composition of the silicon compound for the second layer consists of Si, O, and N. This means, as described above, materials containing Si, O, and N can also be used to make the second layer.

In summary, an active layer constituted as described in this embodiment of the present invention, in which the second layer serves as a carrier-blocking layer, allows for faster carrier injection in the directions parallel to the substrate within the first layer. Since the silicon nanoparticles exist across at least one of the interfacial boundaries between the first layer and the second layer, furthermore, the tunnel effect is likely to occur, and carriers can migrate selectively toward the silicon nanoparticles also in the directions perpendicular to the substrate.

### Manufacturing Method

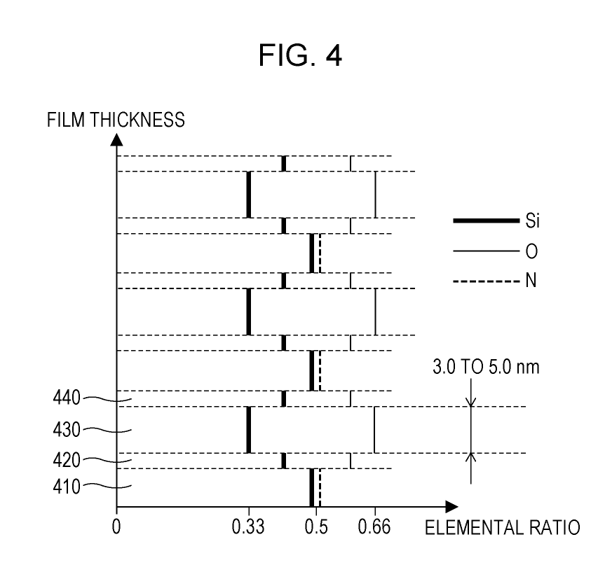

The following describes a method for manufacturing an active layer according to this embodiment with reference to FIG. 4.

First, a layered film structure is formed. More specifically, the following series of steps is repeated two or more times: forming a film from a first silicon compound 410 (a first film), a second silicon compound 420 (a second film), a third silicon compound 430 (a third film), and then a fourth silicon compound 440 (a fourth film).

The first silicon compound 410 has a different composition from the second to fourth (420, 430, and 440). The second to fourth silicon compounds share the same composition.

For example, the first silicon compound 410 is composed of Si and N, whereas the second to fourth (420, 430, and 440) Si and O.

And, the first silicon compound 410, the second silicon compound 420, and the fourth silicon compound 440 contain more silicon than derived from the corresponding stoichiometric compositions, whereas the third silicon compound 430 has the stoichiometric composition. When a silicon compound forms a gradient film, in which the amount of silicon gradually varies in the direction of stacking, the amount of silicon may represent that measured at the middle of the gradient film.

FIG. 4 illustrates an exemplary combination of compositions: the first silicon compound 410 has a composition of SiₓN₄ (x>3), the second silicon compound 420 SiₓO₂ (x>1), the third silicon compound 430 SiO₂, and the fourth silicon compound 440 SiₓO₂ (x>1).

The first silicon compound 410 and the second silicon compound 420 contain more silicon than derived from the corresponding stoichiometric compositions Si₃N₄ and SiO₂, respectively. Thus, silicon nanocrystals grow in these films to extend beyond the interfacial boundaries between the low-band-gap layer (the first layer 110 in FIG. 1) and the high-band-gap layer (the second layer 120 in FIG. 1).

In FIG. 1, the second layer 120 has a region containing no silicon nanoparticles. This layer has the stoichiometric composition, and therefore in this layer the band gap is greater than in any other layers having a nonstoichiometric composition. This type of second layer prevents the carriers trapped in the first layer 110 from overflowing and improves the efficiency of recombination.

The films serving as this second layer 120 should have a total thickness that ensures the second silicon compound 420 and the fourth silicon compound 440 let the third silicon compound 430 have the stoichiometric composition. The films next to the third silicon compound 430 have an effect on the third silicon compound 430 when the distance between them is equal to or shorter than about several times the lattice constant. Thus, films of the third silicon compound 430, which has the stoichiometric composition, can be formed when the thickness of the third silicon compound 430 is equal to or larger than 3 nm, or in other words equal to or larger than six to eight times the lattice constant of SiO₂.

When this third silicon compound 430 containing SiO₂ is too thick, the carrier penetration by diffusion is slowed, and the light-emitting device requires a high voltage to drive; thus, the thickness of the third silicon compound 430 is chosen from a range of 3 to 50 nm. Desirably, the thickness of the third silicon compound 430 is in a range of 3 to 5 nm, with which electrons can migrate by direct tunneling.

The sum of the thickness of the first silicon compound 410 and the second silicon compound 420 is approximately equal to the diameter of the silicon nanoparticles and in a range of 1 to 20 nm. This sum of thickness is determined by the desired diameter of silicon nanoparticles, or in other words the desired emission wavelength of the light-emitting device. For devices emitting visible light, this sum of thickness is chosen in a range of 1 to 3 nm, and for devices emitting near-infrared light, 3 to 20 nm.

At the completion of film formation, the layered film structure may contain or free from silicon nanocrystals, and each of the constituting films may be amorphous or polycrystalline.

The layered film structure having the composition given in FIG. 4 can be formed by known layered film formation techniques, such as sputtering, vapor deposition, and chemical vapor deposition (CVD).

The obtained layered film structure, which has the composition of FIG. 4, is then annealed in a furnace at approximately 1000° C. for about an hour to have silicon nanoparticles formed therein. In this way, an active layer according to this embodiment is obtained (see FIG. 1).

High-temperature annealing makes silicon atoms, a constituent element of the layered films, move to the interfacial boundaries existing between the layered films and crystallize into silicon nanoparticles in an amount larger than derived from the stoichiometric composition. The size and number density of the crystalline silicon nanoparticles are determined by the composition of the individual silicon compounds, the annealing temperature, and the annealing time.

In comparison of the constitution illustrated in FIG. 4 with that in FIG. 1, the first silicon compound 410 roughly corresponds to the first layer 110, and the second to fourth (420, 430, and 440) constitute the second layer 120 in FIG. 1.

However, these relationships do not always strictly apply because atoms migrate beyond the interfacial boundaries between the silicon compounds in FIG. 4 during the annealing process. A more detailed explanation is as follows: the first layer contains silicon nanoparticles, and a silicon nitride composed of the constituting elements of the first silicon compound; the second layer contains in its middle portion silicon nanoparticles, and silicon oxides individually composed of the constituent elements of the second to fourth silicon compounds; on its surface, however, the second layer may retain a silicon compound composed of the constituting elements of the first and second silicon compounds, namely Si, N, and O.

### Second Embodiment

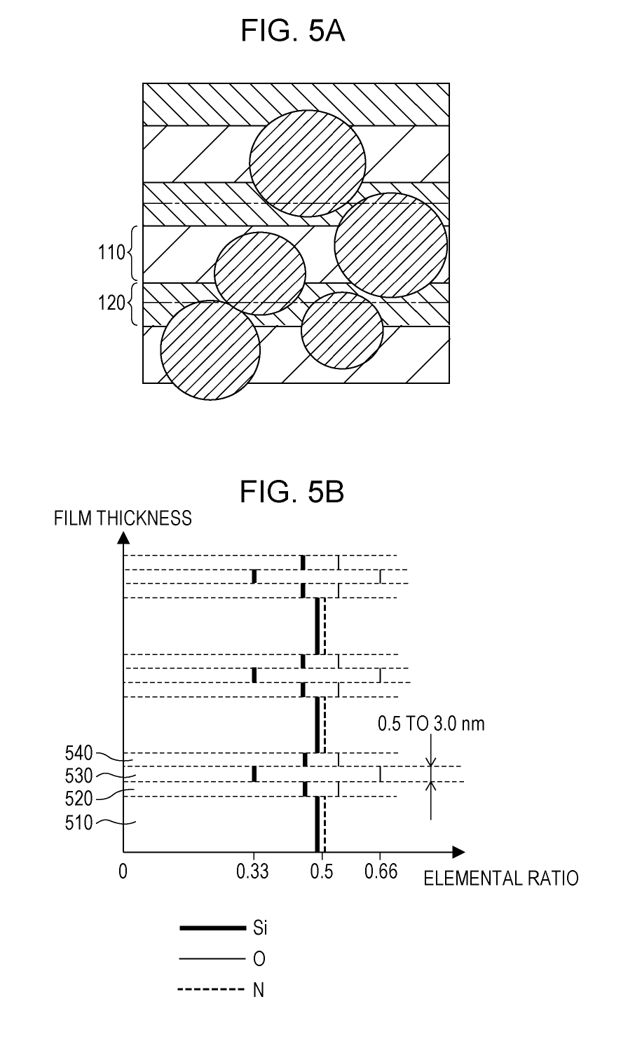

The following describes another embodiment of the present invention with reference to FIGS. 5A and 5B.

FIG. 5A is a diagram illustrating a cross-section of an active layer according to this embodiment, where the composition of the first layer 110 consists of Si and N, and that of the second layer 120 either Si and O or Si, O, and N.

As can be seen from FIG. 5B, FIG. 5A illustrates a layered film structure obtained by repeating the following series of steps: forming a film from a first silicon compound 510, a second silicon compound 520, a third silicon compound 530, and then a fourth silicon compound 540.

The first silicon compound 510 and the second silicon compound 520 contain more silicon than derived from the corresponding stoichiometric compositions Si₃N₄ and SiO₂, respectively, and silicon nanocrystals grow to extend beyond the interfacial boundaries between the low-band-gap layer (the first layer 110 in FIG. 5A) and the high-band-gap layer (the second layer 120 in FIG. 5A).

The second layer 120 in FIG. 5A does not have the stoichiometric composition in any of its constituting films. This type of constitution helps carriers move in the directions perpendicular to the substrate and thus is of particular usefulness when used in, for example, light-emitting devices having a layered active layer portion.

As a constituting film of this second layer 120, the third silicon compound 530 should be thinned to some extent.

The films next to the third silicon compound 530 have an effect on the third silicon compound 530 when the distance between them is equal to or shorter than about several times the lattice constant. Thus, the third silicon compound 530 can contain some portions of silicon nanoparticles therein when the thickness of the third silicon compound 530 is smaller than 3 nm, or in other words smaller than six to eight times the lattice constant of SiO₂.

SiO₂, the stoichiometric composition, has a lattice constant on the order of 0.4 to 0.5 nm, and thus the thickness of the third silicon compound 530 is chosen from a range of 2.4 to 3 nm. The sum of the thickness of the first silicon compound 510 and the second silicon compound 520 is approximately equal to the diameter of the silicon nanoparticles and in a range of 1 to 20 nm. This sum of thickness is determined by the desired diameter of silicon nanoparticles, or in other words the desired emission wavelength of the light-emitting device. For devices emitting visible light, this sum of thickness is chosen in a range of 1 to 3 nm, and for devices emitting near-infrared light, 3 to 20 nm.

As in the first embodiment, the active layer of FIG. 5A is obtained by annealing the layered film structure of FIG. 5B at approximately 1000° C. for about an hour.

In comparison of FIG. 5B with the non-annealed layered film structure according to the first embodiment (FIG. 4), the thickness is smaller in FIG. 5B than in FIG. 4. In FIG. 5A, furthermore, silicon atoms have migrated beyond the third silicon compound 530, and silicon nanoparticles exist across the middle of the second layer 120.

### Third Embodiment

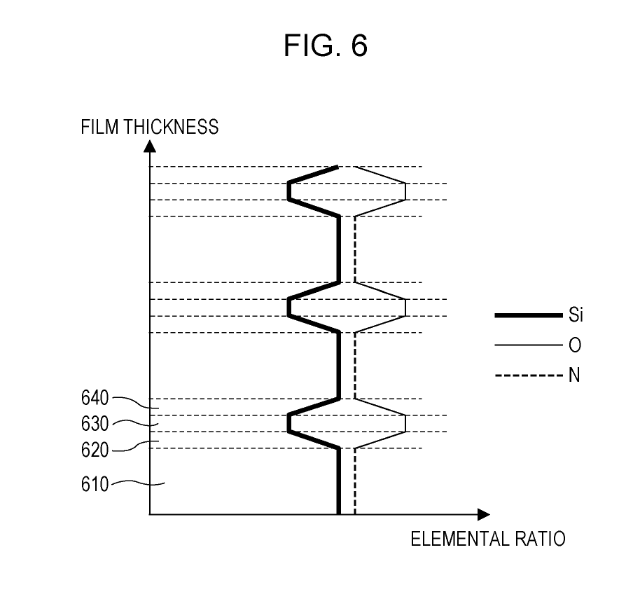

FIG. 6 is a diagram explaining another manufacturing method. FIG. 6 illustrates a compositional distribution of silicon compounds before the formation of silicon nanoparticles. A first silicon compound 610 and a third silicon compound 630, which contains less silicon than the first, have a second silicon compound 620 having a gradually changing composition put therebetween. Similarly, a fourth silicon compound 640 has a composition gradually changing from the composition of the third silicon compound 630 to that of the first silicon compound 610. These gradual compositional changes relax the gap of the amount of silicon often seen in layered film structures; as a result, silicon nanoparticles can more easily grow beyond at least one of the interfacial boundaries between the first and second layers during the annealing process.

In addition, these embodiments of the present invention, described above with reference to drawings, improve the efficiency of injection whether the injected carriers are electrons or holes.

Although in the embodiments described above the silicon compounds consist of either Si and O or Si and N, this is not the only constitution that can be used in the active layer and its manufacturing method according to the present invention. The composition of each silicon compound can be any appropriate combination of Si, O, N, and C.

Furthermore, the active layer described above can be used in combination with electrodes for injecting carriers to form a silicon light-emitting device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-256310 filed Nov. 16, 2010, which is hereby incorporated by reference herein in its entirety.

What is claimed is:

1. An active layer for silicon light-emitting devices, comprising:
a layered film structure of a first layer and a second layer alternately stacked on a substrate, the first layer containing a silicon compound whereas the second layer containing another silicon compound and having a larger band gap than the first layer; and
a plurality of silicon nanoparticles contained in the layered film structure and emitting light on carrier injection, wherein:
the first layer contains more silicon atoms than the second layer; and
at least one of the silicon nanoparticles exists across at least one of interfacial boundaries between the first layer and the second layer.

2. The active layer according to claim 1, wherein
the silicon nanoparticles are formed to exist across both the interfacial boundaries between the first layer and the second layer.

3. The active layer according to claim 1, wherein
the silicon compound contained in the first layer is composed of silicon and carbon.

4. The active layer according to claim 3, wherein
the silicon compound contained in the second layer is composed of either silicon and oxygen or silicon and nitrogen.

5. The active layer according to claim 1, wherein
the silicon compound contained in the first layer is composed of silicon and nitrogen.

6. The active layer according to claim 5, wherein
the silicon compound contained in the second layer is composed of either silicon and oxygen or silicon, nitrogen, and oxygen.

7. A silicon light-emitting device comprising:
the active layer according to claim 1; and
an electrode for injecting a carrier into the active layer.

8. A method for manufacturing an active layer for silicon light-emitting devices, comprising:
forming a first film containing a first silicon compound;
forming a second film on the first film, the second film containing a second silicon compound having a different composition from the first silicon compound;
forming a third film on the second film, the third film containing a third silicon compound sharing the same composition with the second silicon compound but containing less silicon than the second silicon compound;
forming a fourth film on the third film, the fourth film containing a fourth silicon compound sharing the same composition with the third silicon compound but containing more silicon than the third silicon compound; and
annealing the first to fourth films to form silicon nanoparticles emitting light on carrier injection.

9. The method for manufacturing an active layer according to claim 8, wherein
an elemental ratio of the second silicon compound and that of the fourth silicon compound gradually vary in a direction of stacking.

10. The method for manufacturing an active layer according to claim 8, wherein
the steps of forming the first to fourth films are repeated two or more times.

11. The method for manufacturing an active layer according to claim 8, wherein
the silicon nanoparticles are formed to exist across at least one of interfacial boundaries between a first layer and a second layer, the first layer containing a silicon compound whereas the second layer containing another silicon compound and having a larger band gap than the first silicon layer.
